(19) United States
(12) Patent Application Publication
(10) Pub. No.: US 2024/0240995 A1
(43) Pub. Date: Jul. 18, 2024

(54) TEMPERATURE SENSOR LINEARIZATION TECHNIQUES

(71) Applicant: Micron Technology, Inc., Boise, ID (US)

(72) Inventors: Luiza Souza Correa, Munich (DE); Julius Löckemann, Munich (DE); Elena Cabrera Bernal, Munich (DE); Martin Brox, Munich (DE); Jun Tan, Weißenfeld (DE)

(21) Appl. No.: 18/404,610

(22) Filed: Jan. 4, 2024

Related U.S. Application Data
(60) Provisional application No. 63/480,122, filed on Jan. 17, 2023.

(51) Int. Cl. G01K 13/10; G01K 1/02; G01K 7/14

(52) U.S. Cl. CPC G01K 13/10; G01K 1/026; G01K 7/14

(57) ABSTRACT

Methods, systems, and devices for temperature sensor linearization techniques are described. A temperature sensor associated with a semiconductor device may include a first circuit and a second circuit. The second circuit may be configured to determine that a first temperature, associated with the semiconductor device and indicated by one or more first bits generated by the first circuit, is within a first temperature range of a total temperature range measurable by the temperature sensor. The second circuit may be configured to generate and output, based on the first temperature being within the first temperature range, one or more second bits indicating a second temperature associated with the semiconductor device. The second circuit may generate the one or more second bits by applying, to the one or more first bits, a first-order operation corresponding to the first temperature range and associated with correcting an error of the first temperature.

### CROSS REFERENCE

The present Application for Patent claims priority to U.S. Patent Application No. 63/480, 122 by Souza Correa et al., entitled “TEMPERATURE SENSOR LINEARIZATION TECHNIQUES,” filed Jan. 17, 2023, which is assigned to the assignee hereof, and which is expressly incorporated by reference in its entirety herein.

### TECHNICAL FIELD

The following relates to one or more systems for memory, including temperature sensor linearization techniques.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 illustrates an example of a system that supports temperature sensor linearization techniques in accordance with examples as disclosed herein.

FIG. 2 illustrates an example of a circuit that supports temperature sensor linearization techniques in accordance with examples as disclosed herein.

FIGS. 3 and 4 illustrate examples of temperature diagrams that support temperature sensor linearization techniques in accordance with examples as disclosed herein.

FIG. 5 illustrates a block diagram of a temperature sensor associated with a semiconductor device that supports temperature sensor linearization techniques in accordance with examples as disclosed herein.

FIG. 6 illustrates a flowchart showing a method or methods that support temperature sensor linearization techniques in accordance with examples as disclosed herein.

### DETAILED DESCRIPTION

A semiconductor device, such as a memory device, a complementary metal-oxide semiconductor (CMOS) device, may include one or more temperature sensors for measuring a temperature of the semiconductor device, or one or more components of the semiconductor device, or both. In some examples, the temperature sensor may output a temperature reading based on comparing one or more signals or currents to a reference signal or current. For example, the temperature sensor may generate a first current (or signal) (e.g., a proportional-to-absolute-temperature (PTAT) current) that is based on an actual temperature measurement of the semiconductor device, as well as a second current (or signal) (e.g., a zero temperature coefficient (0TC or ZTC) current) that corresponds to a reference current. The temperature sensor may generate and output one or more bits representing the measured temperature, for example, based on a difference between the first current to the second current. In some examples, measuring temperature based on such generated currents may, however, fail to compensate for a second-order error over a total temperature range measurable by the temperature sensor (e.g., due to a second-order error associated with a substrate on which the temperature sensor is located), which may result in relatively large errors in the measured temperature. In some examples, the temperature sensor may include a linearization circuit configured to apply a second-order operation to generated temperature bits in an attempt to at least partially correct the second-order error, thereby resulting in a more accurate temperature measurement. However, a linearization circuit that implements second-order error correction may be complex and may occupy a large silicon area of the semiconductor device relative to a temperature sensor without such a linearization circuit, as well as consuming excessive power, among other disadvantages.

The techniques described herein may mitigate large chip area usage and excessive power consumption while supporting the correction of second-order error associated with temperature measurements by implementing a linearization circuit configured to apply a first-order error correction operation based on a temperature range that a temperature measurement is or should fall within. For example, a total temperature range measurable by a temperature sensor of a semiconductor device (e.g., a portion of the total temperature range) may be split (e.g., partitioned, divided) into multiple temperature ranges (e.g. regions). Using a linearization circuit, the temperature sensor, for example, may apply a respective first-order operation for a respective temperature range to bits representing one or more temperature measurements of the semiconductor device, where each first-order operation may be determined based on an error associated with a corresponding temperature range. Applying the respective first-order operations to the bits may at least partially correct a second-order error of the corresponding temperature measurements, resulting in a more accurate output. For example, the second-order error may be parabolic (e.g., non-linear) over the total temperature range, but may be relatively linear within each of the multiple temperature ranges, and first-order operations may be used to correct linear error with a relatively high degree of accuracy. Thus, by applying the respective first-order operations, the relatively linear error within each temperature range may be corrected accordingly, which will result in a relatively accurate correction of the second-order error across the total temperature range. Additionally, using the respective first-order operations will reduce a total chip area of a linearization circuit compared to applying a complex linearization process using second-order operations, resulting in increased efficiency and speed in calculations, as well as lower power consumption and lower latency, among other benefits.

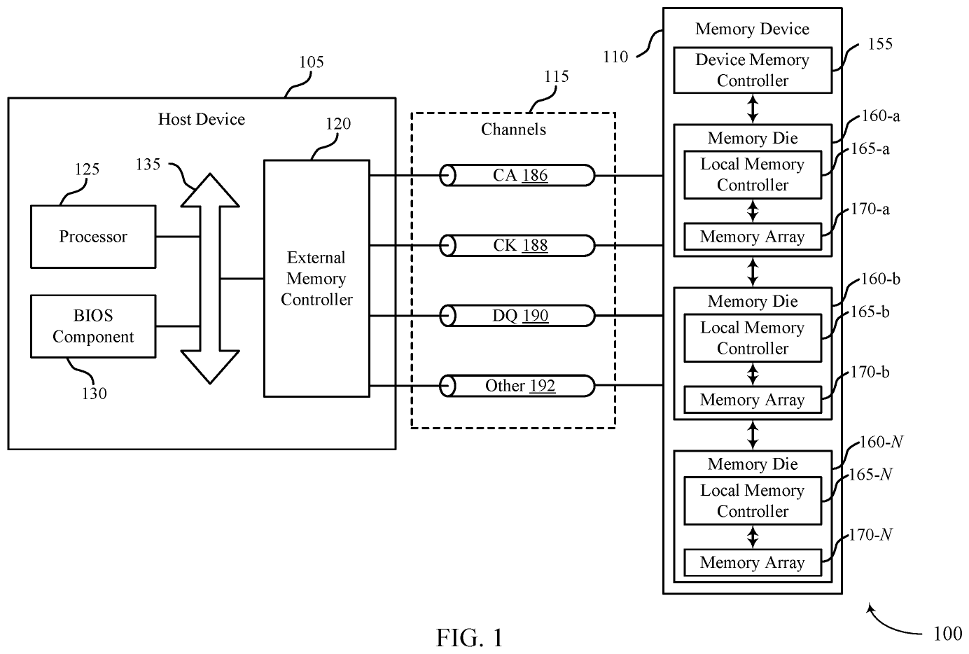

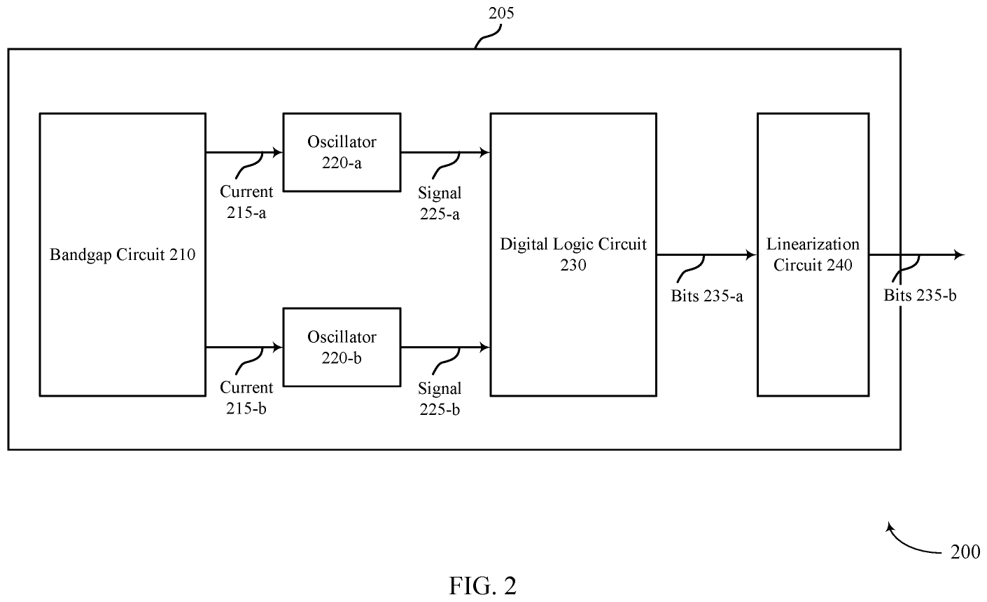

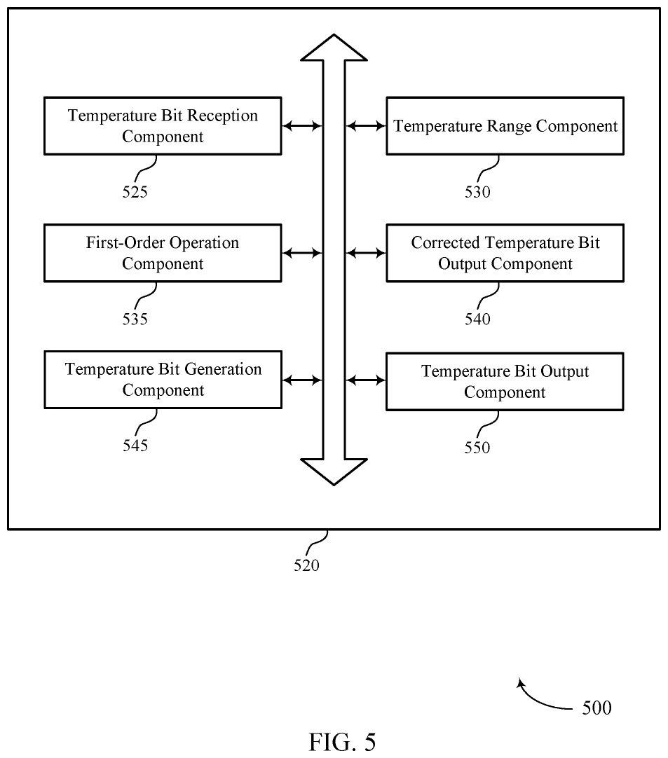

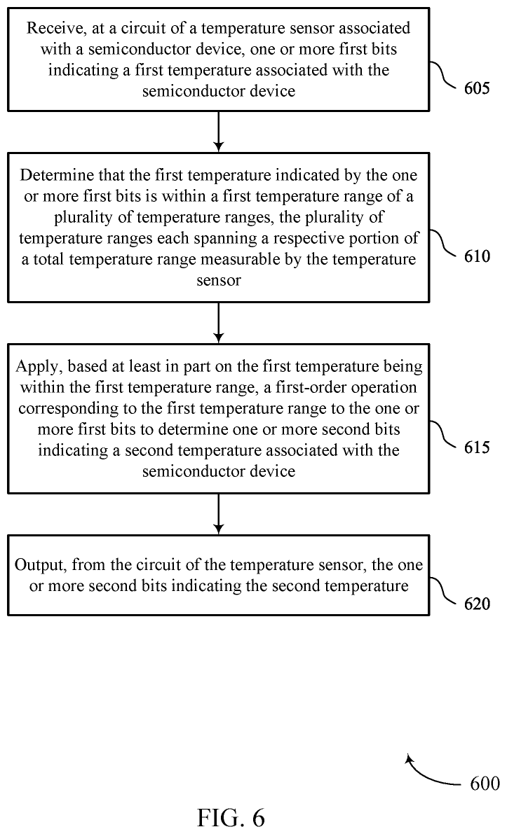

Features of the disclosure are initially described in the context of systems and dies as described with reference to FIG. 1. Features of the disclosure are described in the context block diagrams and temperature diagrams as described with reference to FIGS. 2 through 4. These and other features of the disclosure are further illustrated by and described with reference to an apparatus diagram and flowcharts that relate to temperature sensor linearization techniques as described with reference to FIGS. 5 and 6.

FIG. 1 illustrates an example of a system 100 that supports temperature sensor linearization techniques in accordance with examples as disclosed herein. The system 100 may include a host device 105, a memory device 110, and a plurality of channels 115 coupling the host device 105 with the memory device 110. The system 100 may include one or more memory devices 110, but aspects of the one or more memory devices 110 may be described in the context of a single memory device (e.g., memory device 110).

The system 100 may include portions of an electronic device, such as a computing device, a mobile computing device, a wireless device, a graphics processing device, a vehicle, or other systems. For example, the system 100 may illustrate aspects of a computer, a laptop computer, a tablet computer, a smartphone, a cellular phone, a wearable device, an internet-connected device, a vehicle controller, or the like. The memory device 110 may be a component of the system 100 that is operable to store data for one or more other components of the system 100.

Portions of the system 100 may be examples of the host device 105. The host device 105 may be an example of a processor (e.g., circuitry, processing circuitry, a processing component) within a device that uses memory to execute processes, such as within a computing device, a mobile computing device, a wireless device, a graphics processing device, a computer, a laptop computer, a tablet computer, a smartphone, a cellular phone, a wearable device, an internet-connected device, a vehicle controller, a system on a chip (SoC), or some other stationary or portable electronic device, among other examples. In some examples, the host device 105 may refer to the hardware, firmware, software, or any combination thereof that implements the functions of an external memory controller 120. In some examples, the external memory controller 120 may be referred to as a host (e.g., host device 105).

A memory device 110 may be an independent device or a component that is operable to provide physical memory addresses/space that may be used or referenced by the system 100. In some examples, a memory device 110 may be configurable to work with one or more different types of host devices. Signaling between the host device 105 and the memory device 110 may be operable to support one or more of: modulation schemes to modulate the signals, various pin configurations for communicating the signals, various form factors for physical packaging of the host device 105 and the memory device 110, clock signaling and synchronization between the host device 105 and the memory device 110, timing conventions, or other functions.

The memory device 110 may be operable to store data for the components of the host device 105. In some examples, the memory device 110 (e.g., operating as a secondary-type device to the host device 105, operating as a dependent-type device to the host device 105) may respond to and execute commands provided by the host device 105 through the external memory controller 120. Such commands may include one or more of a write command for a write operation, a read command for a read operation, a refresh command for a refresh operation, or other commands.

The host device 105 may include one or more of an external memory controller 120, a processor 125, a basic input/output system (BIOS) component 130, or other components such as one or more peripheral components or one or more input/output controllers. The components of the host device 105 may be coupled with one another using a bus 135.

The processor 125 may be operable to provide functionality (e.g., control functionality) for the system 100 or the host device 105. The processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination of these components. In such examples, the processor 125 may be an example of a central processing unit (CPU), a graphics processing unit (GPU), a general purpose GPU (GPGPU), or an SoC, among other examples. In some examples, the external memory controller 120 may be implemented by or be a part of the processor 125.

The BIOS component 130 may be a software component that includes a BIOS operated as firmware, which may initialize and run various hardware components of the system 100 or the host device 105. The BIOS component 130 may also manage data flow between the processor 125 and the various components of the system 100 or the host device 105. The BIOS component 130 may include instructions (e.g., a program, software) stored in one or more of read-only memory (ROM), flash memory, or other non-volatile memory.

The memory device 110 may include a device memory controller 155 and one or more memory dies 160 (e.g., memory chips) to support a capacity (e.g., a desired capacity, a specified capacity) for data storage. Each memory die 160 (e.g., memory die 160-a, memory die 160-b, memory die 160-N) may include a local memory controller 165 (e.g., local memory controller 165-a, local memory controller 165-b, local memory controller 165-N) and a memory array 170 (e.g., memory array 170-a, memory array 170-b, memory array 170-N). A memory array 170 may be a collection (e.g., one or more grids, one or more banks, one or more tiles, one or more sections) of memory cells, with each memory cell being operable to store one or more bits of data. A memory device 110 including two or more memory dies 160 may be referred to as a multi-die memory or a multi-die package or a multi-chip memory or a multi-chip package.

The device memory controller 155 may include components (e.g., circuitry, logic) operable to control operation of the memory device 110. The device memory controller 155 may include hardware, firmware, or instructions that enable the memory device 110 to perform various operations and may be operable to receive, transmit, or execute commands, data, or control information related to the components of the memory device 110. The device memory controller 155 may be operable to communicate with one or more of the external memory controller 120, the one or more memory dies 160, or the processor 125. In some examples, the device memory controller 155 may control operation of the memory device 110 described herein in conjunction with the local memory controller 165 of the memory die 160.

A local memory controller 165 (e.g., local to a memory die 160) may include components (e.g., circuitry, logic) operable to control operation of the memory die 160. In some examples, a local memory controller 165 may be operable to communicate (e.g., receive or transmit data or commands or both) with the device memory controller 155. In some examples, a memory device 110 may not include a device memory controller 155, and a local memory controller 165 or the external memory controller 120 may perform various functions described herein. As such, a local memory controller 165 may be operable to communicate with the device memory controller 155, with other local memory controllers 165, or directly with the external memory controller 120, or the processor 125, or any combination thereof. Examples of components that may be included in the device memory controller 155 or the local memory controllers 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, or various other components operable for supporting described operations of the device memory controller 155 or local memory controller 165 or both.

The external memory controller 120 may be operable to enable communication of information (e.g., data, commands, or both) between components of the system 100 (e.g., between components of the host device 105, such as the processor 125, and the memory device 110). The external memory controller 120 may process (e.g., convert, translate) communications exchanged between the components of the host device 105 and the memory device 110. In some examples, the external memory controller 120, or other component of the system 100 or the host device 105, or its functions described herein, may be implemented by the processor 125. For example, the external memory controller 120 may be hardware, firmware, or software, or some combination thereof implemented by the processor 125 or other component of the system 100 or the host device 105. Although the external memory controller 120 is depicted as being external to the memory device 110, in some examples, the external memory controller 120, or its functions described herein, may be implemented by one or more components of a memory device 110 (e.g., a device memory controller 155, a local memory controller 165) or vice versa.

The components of the host device 105 may exchange information with the memory device 110 using one or more channels 115. The channels 115 may be operable to support communications between the external memory controller 120 and the memory device 110. Each channel 115 may be an example of a transmission medium that carries information between the host device 105 and the memory device 110. Each channel 115 may include one or more signal paths (e.g., a transmission medium, a conductor) between terminals associated with the components of the system 100. A signal path may be an example of a conductive path operable to carry a signal. For example, a channel 115 may be associated with a first terminal (e.g., including one or more pins, including one or more pads) at the host device 105 and a second terminal at the memory device 110. A terminal may be an example of a conductive input or output point of a device of the system 100, and a terminal may be operable to act as part of a channel.

Channels 115 (and associated signal paths and terminals) may be dedicated to communicating one or more types of information. For example, the channels 115 may include one or more command and address (CA) channels 186, one or more clock signal (CK) channels 188, one or more data (DQ) channels 190, one or more other channels 192, or any combination thereof. In some examples, signaling may be communicated over the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols (e.g., signal levels) of a signal may be registered for each clock cycle (e.g., on both a rising edge and a falling edge of a clock signal).

The techniques described herein may mitigate large chip area usage and excessive power consumption while supporting the correction of second-order error associated with temperature measurements by implementing a linearization circuit configured to apply a first-order error correction operation based on a temperature range that a temperature measurement is or should fall within. In some examples, a total temperature range measurable by a temperature sensor of a semiconductor device, such as the memory device 110 (or a CMOS device), may be split (e.g., partitioned, divided) into multiple temperature ranges, or regions. For example, using a first-order linearization circuit, a temperature sensor of the memory device 110 may apply a respective first-order operation corresponding to a respective temperature range of the multiple temperature ranges to bits representing one or more temperature measurements that are within the respective temperature range. Such application of a first-order operation to the bits may at least partially correct the second-order error of the temperature measurements. For example, the first-order operations may correct a relatively linear error of the second-order error within each temperature range, resulting in an accurate correction of the second-order error over the total temperature range. In some cases, applying the one or more first-order operations may reduce a total chip area of a linearization circuit compared to applying a complex linearization process (e.g., using second-order operations), resulting in increased efficiency and speed in calculations, as well as lower power consumption and lower latency, as described herein.

FIG. 2 illustrates an example of a circuit 200 that supports temperature sensor linearization techniques in accordance with examples as disclosed herein. In some examples, the circuit 200 may implement aspects of a system 100 as described with reference to FIG. 1. For example, the circuit 200 may include a temperature sensor 205, where the temperature sensor 205 may be coupled with or included in a semiconductor device, such as a memory device 110, one or more memory dies 160, a host device 105, or any combination thereof as described with reference to FIG. 1. In some cases, the semiconductor device may include the temperature sensor 205, where the temperature sensor 205 may be configured to measure a temperature of the semiconductor device or one or more components of the semiconductor device. For example, the temperature sensor 205 may represent a temperature sensor of one or more components (e.g., of one or more memory dies 160) of the semiconductor device. In some examples, the semiconductor device may be an example of a memory device (e.g., the memory device 110). Additionally, or alternatively, the semiconductor device may be an example of a CMOS device, or any other type of semiconductor device. In some cases, the semiconductor device may include multiple temperature sensors 205 (e.g., each configured to measure a temperature of a respective component or region of the semiconductor device). The temperature sensor 205 may be configured to mitigate a second-order error by implementing a linearization circuit configured to apply respective first-order operations for multiple temperature ranges of an overall temperature range measurable by the temperature sensor 205.

In some examples, the temperature sensor 205 may include a bandgap circuit 210, which may generate one or more currents 215 used to measure a temperature of the semiconductor device (e.g., one or more components of the semiconductor device). For example, the bandgap circuit 210 may generate a current 215-a that is based on a temperature of the semiconductor device. In some examples, the current 215-a may be an example of a PTAT current and may be referred to as I_{PTAT}. In some cases, the current 215-a (e.g., I_{PTAT}) may have a proportional relationship to the temperature of the semiconductor device. For example, I_{PTAT} may have a linear relationship to an actual temperature of the semiconductor device, where I_{PTAT} may increase linearly with the temperature of the semiconductor device. Additionally, the bandgap circuit 210 may generate a current 215-b. In some examples, the current 215-b may be an example of a 0TC current and may be referred to as I_{0TC}. In some cases, the current 215-b (e.g., I_{0TC}) may be a constant current, where the current 215-b may remain the same regardless of a temperature of the semiconductor device (or the components). In some examples, the current 215-b may represent a reference current. That is, the current 215-b (e.g., a signal 225 generated based on the current 215-b) may be used as a reference (e.g., a baseline) against which the current 215-a (e.g., a signal 225 generated based on the current 215-a) may be compared to determine a temperature measurement. In some examples, the bandgap circuit 210 may output the current 215-a and the current 215-b (and/or one or more additional currents 215) to one or more oscillators 220.

The temperature sensor 205 may include one or more oscillators 220 coupled with the bandgap circuit 210 for converting the currents 215 into one or more signals 225, where the signals 225 may be associated with one or more frequencies. For example, the current 215-a may be a direct current (DC). In some examples, the temperature sensor 205 may include an oscillator 220-a, where the oscillator 220-a may include one or more capacitors. The oscillator 220-a may receive the DC (e.g., the current 215-a), may charge the one or more capacitors using the DC, and may discharge (e.g., repeatedly) the one or more capacitors to generate a signal 225-a having a corresponding frequency, where the frequency may be referred to as f_{PTAT}. In some examples, the signal 225-a may be an alternating current (AC) generated based on the DC (e.g., having a frequency that is based on an amplitude or magnitude of the DC). Additionally, or alternatively, the temperature sensor 205 may include an oscillator 220-b, where the oscillator 220-b may generate a signal 225-b based on charging and discharging one or more capacitors of the oscillator 220-b using the current 215-b, where the signal 225-b may represent an AC, and the current 215-b may represent a DC. In some examples, a frequency of the signal 225-b may be referred to as f_{0TC}. The oscillator 220-a and the oscillator 220-b may output the signals 225-a and 225-b, respectively, to a digital logic circuit 230.

The temperature sensor 205 may include the digital logic circuit 230 for generating and outputting one or more bits 235-a that are indicative of the temperature of the semiconductor device based on the signals 225. For example, the digital logic circuit 230 may receive the signal 225-a and the signal 225-b corresponding to respective frequencies, and may generate the one or more bits 235-a based on comparing the signal 225-a to the signal 225-b. In some examples, the signal 225-b may be a reference signal, where the signal 225-b may have a constant frequency (e.g., f_{0TC}) based on a constant current of the current 215-b (e.g., I_{0TC}). As such, a relative difference between a frequency of the signal 225-a and a frequency of the signal 225-b may be indicative of the temperature of the semiconductor device. The digital logic circuit 230 may include circuitry for comparing the signal 225-a to the signal 225-b (e.g., comparing f_{PTAT} to f_{0TC}), and may generate and output the one or more bits 235-a based on the comparison.

The one or more bits 235-a may represent a first temperature of the semiconductor device. The temperature sensor 205 may output one or more bits 235-a for multiple temperatures of the semiconductor device by generating one or more bits 235-a for multiple temperatures and corresponding currents 215 and signals 225 over time. In some examples, the one or more bits 235-a may include a defined quantity of bits (e.g., 7 bits, defined in accordance with a standard, such as a JEDEC standard) to represent a digital code corresponding to a temperature. For example, the digital code may be mapped a corresponding temperature value. In some examples. the temperature sensor 205 may exclude the oscillator 220-a and the oscillator 220-b, where the digital logic circuit 230 may generate and output the one or more bits 235-a based on comparing the current 215-a (e.g., I_{PTAT}) to the current 215-b (e.g., I_{0TC}).

In some examples, the semiconductor device may control a self-refresh rate, tune an internal voltage, or adjust various trim parameters, among other adjustments to maintain or improve a performance of the semiconductor device based on the temperature output by the temperature sensor 205. In some cases, determining the one or more bits 235-a using the bandgap circuit 210, the oscillators 220, and the digital logic circuit 230 may occupy a relatively small area of a substrate (e.g., a silicon area) associated with the semiconductor device. In some examples, the temperature sensor 205 may be implemented in very large-scale integration (VLSI), where in VLSI the semiconductor device may include a multitude of semiconductor devices including the temperature sensor 205, the components of the temperature sensor 205, as well as other components (e.g., of the semiconductor device) on a single chip. In some cases, the semiconductor device, the temperature sensor 205, and the components of the temperature sensor 205 may be used in other circuit configurations.

The one or more bits 235-a may be associated with a second-order error over a temperature range measurable by the temperature sensor 205. For example, the bandgap circuit 210, the temperature sensor 205, the semiconductor device, or any combination thereof, may be located over or formed based on a substrate (e.g., silicon), where one or more properties of the substrate may change with respect to temperature. The current 215-a and the corresponding signal 225-a may be associated with a second-order error based on the change in properties of the substrate. For example, the current 215-a may be different from a current representing an actual temperature of the semiconductor device, and the signal 225-a may similarly be different from a signal representing the actual temperature, where differences over multiple temperatures may represent a second-order error (e.g., parabolic) over the total temperature range measurable by the temperature sensor 205. Similarly, the current 215-b and the signal 225-b may change based on the properties of the substrate, and may be associated with a second-order error over the total temperature range. The second-order error present in the currents 215 and the signals 225 may result in a second-order error in the one or more bits 235-a compared to bits representing an actual temperature of the semiconductor device. In some examples, the temperature sensor 205 may include a linearization circuit 240 coupled with the digital logic circuit 230 for mitigating the second-order error present in the one or more bits 235-a. For example, an actual temperature of the semiconductor device may have a linear relation to one or more code values over temperature, where the linearization circuit 240 may linearize a second-order temperature relation of the one or more bits 235-a by implementing one or more second-order operations to more accurately fit to the actual temperature of the semiconductor device.

In some examples, the linearization circuit 240 may implement a multiply and accumulate method including a second-order error correction operation to at least partially linearize the one or more bits 235-a, which may result in an accurate temperature with low error. For example, the linearization circuit may include circuitry to apply a second-order equation, such as D_{LIN}=a₁D_{NL}²+a₂D_{NL}+a₃. Here, D_{LIN} may represent a linearized curve based on implementing weighted values a₁, a₂, and a₃ and a variable D_{NL}, and D_{NL} may be a value (e.g., a code) of the one or more bits 235-a over temperature. However, implementing a multiply and accumulate method may include a large quantity of complex, floating-point calculations using second-order operations (e.g., equations) to compensate for the second-order error, which may result in the linearization circuit 240 occupying a large silicon area to accommodate associated circuitry. Second-order operation application may also lead to relatively high power consumption, high latency and complexity in operations, additional manufacturing costs, among other disadvantages.

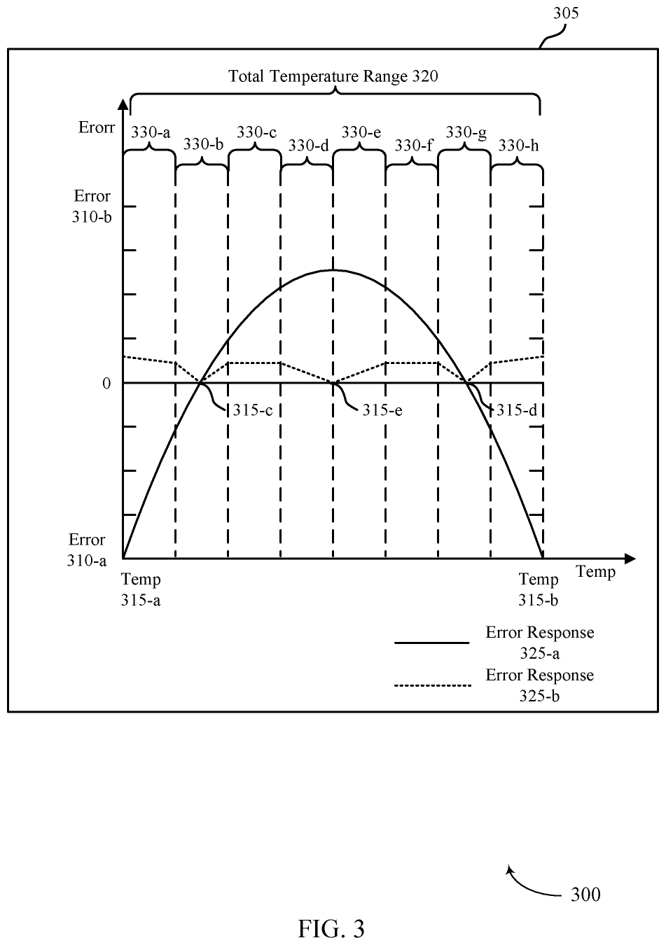

As described herein, the temperature sensor 205 may include a linearization circuit 240 implementing one or more first-order operations to mitigate large chip area usage and excessive power consumption while correcting a second-order error of temperature measurements. In some examples, the semiconductor device or temperature sensor 205 may split a total temperature range into multiple temperature ranges, or regions, with corresponding first-order operations as described with reference to FIG. 3. To at least partially correct a second-order error associated with the one or more bits 235-a, the temperature sensor 205 may apply a first-order operation to the one or more bits 235-a that corresponds to a temperature range including the temperature indicated by the one or more bits 235-a.

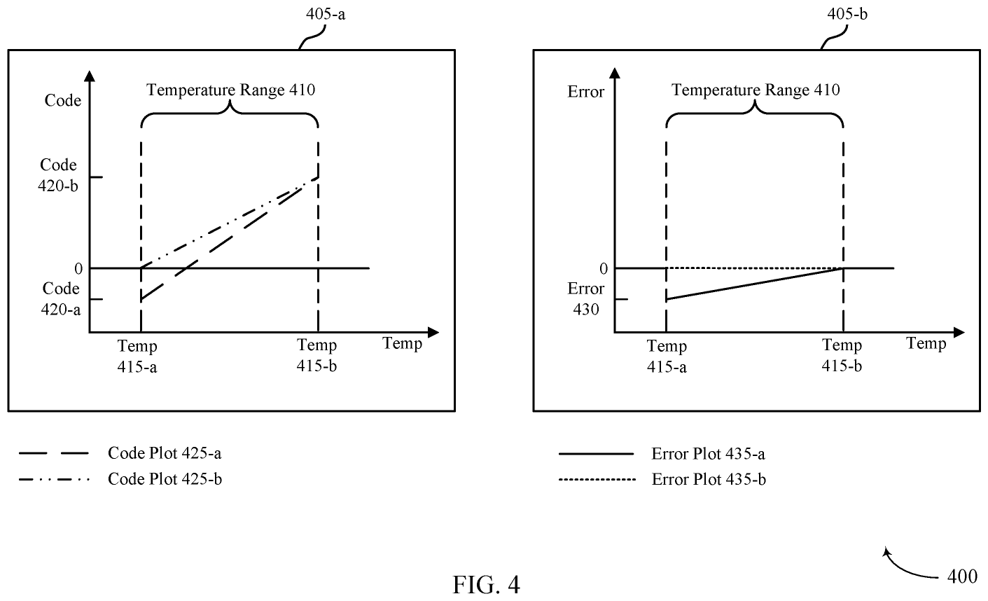

For example, the linearization circuit 240 may receive the one or more bits 235-a and may determine which of the multiple regions a first temperature corresponding to the one or more bits 235-a is within, as described with reference to FIG. 3. After determining that the one or more bits 235-a is within a first temperature range, the linearization circuit 240 may apply a corresponding first-order operation to the one or more bits 235-a to generate the one or more bits 235-b. In some examples, the one or more bits 235-b may correspond to a second, corrected temperature, where the second temperature may be closer to an actual temperature of the semiconductor device, as described with reference to FIGS. 3 and 4. In some cases, the first temperature may be referred to as an input temperature to the linearization circuit 240 and the second temperature may be referred to as an output temperature of the linearization circuit 240. In some cases, the linearization circuit 240) (e.g., the temperature sensor 205) may determine corresponding first-order operations based on a second-order error associated with each temperature range, as described with reference to FIGS. 3 and 4.

In some examples, the linearization circuit 240 may apply the first-order operations to the one or more bits 235-a by routing the one or more bits 235-a through one or more circuit segments. For example, the linearization circuit 240 may include one or more circuit segments, where each circuit segment may be used to apply a corresponding first-order operation. For instance, if the first temperature corresponding to the one or more bits 235-a is within a first temperature range, the linearization circuit 240 may route the one or more bits 235-a through a first segment corresponding to the first temperature range, where the first segment may include circuitry for applying a corresponding first-order operation to the one or more bits 235-a. By routing the one or more bits 235-a through the first segment, the linearization circuit 240) may generate and output the one or more bits 235-b.

The linearization circuit 240 may similarly correct one or more additional bits 235-a corresponding to one or more additional temperatures of the semiconductor device. For example, the linearization circuit 240) may subsequently receive additional bits 235-a corresponding to a third temperature of the semiconductor device (e.g., different from the first temperature measured at a later time), may determine that the third temperature is within a second temperature range (e.g., different from the first temperature range), and may generate additional bits 235-b corresponding to a fourth temperature (e.g., a corrected temperature). In some examples, the linearization circuit 240) may generate the additional bits 235-b by routing the additional bits 235-a through a second segment corresponding to the second temperature range and a second first-order operation (e.g., different from the first-order operation corresponding to the first temperature range). In some examples, the linearization circuit 240 may route any quantity of sets of bits 235-a to generate any quantity of sets of bits 235-b for multiple temperatures across the total temperature range over time.

In some examples, the temperature sensor 205 may extend the bit values of the one or more bits 235-a, 235-b, or both. For example, the one or more bits 235-a and the one or more bits 235-b may be extended to include a quantity of bits (e.g. 10 bits) greater than the defined quantity of bits (e.g., 7 bits). In some examples, doing so may increase an accuracy of calculations while applying the one or more first-order operations to the one or more bits 235-a, resulting in a more accurate output of the one or more bits 235-b. In some examples, the temperature sensor 205 may round the one or more bits 235-b to the defined quantity of bits (e.g., using the linearization circuit 240) or another circuit after the linearization circuit 240) before outputting the one or more bits 235-b. In some examples, the linearization circuit 240) may output the one or more bits 235-b to one or more components of the temperature sensor 205, one or more components of the semiconductor device, or to another device. In some cases, the one or more bits 235-a and the one or more bits 235-b may correspond to one or more codes representing different temperatures of the semiconductor device over time, as described with reference to FIGS. 3 and 4. In some examples, the one or more first-order operations may be one or more trim values, as described with reference to FIG. 3, where the circuit segments may each be configured based on the trim values. In some cases, the circuit segments may include circuitry for performing floating-point operations according to the one or more first-order operations.

Implementing first-order operations in the linearization circuit 240 may result in a more accurate temperature output while reducing a complexity of the linearization circuit 240 compared to applying second-order operations or multiply and accumulate operations. For example, using multiple circuit segments to represent one or more first-order operations corresponding to multiple temperature ranges of a total temperature range may occupy a smaller chip area compared to second-order or multiply and accumulate circuitry. Using first-order operations in the linearization circuit 240 may also reduce a manufacturing cost and complexing of manufacturing the linearization circuit 240. Additionally, or alternatively. applying the first-order operations may reduce a complexity of operations, which may reduce power consumption of the temperature sensor 205 as well as reduce a latency of calculations.

FIG. 3 illustrates an example of a temperature diagram 300 that supports temperature sensor linearization techniques in accordance with examples as disclosed herein. In some examples. the temperature diagram 300 may implement aspects of a system 100 as described with reference to FIG. 1, a circuit 200 as described with reference to FIG. 2, or both. For example, the temperature diagram 300) may depict a graph 305, which may show errors of one or more temperatures measured using a temperature sensor, such as the temperature sensor 205 including the bandgap circuit 210, the one or more oscillators 220, the digital logic circuit 230, and the linearization circuit 240) as described with reference to FIG. 2.

The graph 305 may range from an error 310-a to an error 310-b on an error axis and from a temperature 315-a to a temperature 315-b on a temperature axis, where the temperature axis may represent a total temperature range 320 of a semiconductor device (e.g., a memory device 110 or a CMOS device) that is measurable by the temperature sensor 205. The graph 305 may include plots of error responses 325-a and 325-b. In some cases, the graph 305 may represent a temperature sensor 205 applying one or more first-order operations for multiple temperature ranges 330 of the total temperature range 320 to mitigate a second-order error as described with reference to FIG. 2. In some examples, an error below 0 may represent a temperature value (e.g., ° C.) below a value of an actual temperature of the semiconductor device, while a positive error may represent a temperature value above the value of the actual temperature. In some examples, the error axis may represent an error of a temperature code compared to an actual code. In some cases, the error axis may represent an absolute error of the one or more bits 235-a.

In the example of FIG. 3, a temperature sensor 205 may split the total temperature range 320) of the semiconductor device into 8 temperature ranges 330, including temperature ranges 330)-a through 330-h. In some cases, each temperature range 330 may have a different respective size. For example, each temperature range 330 may span a different quantity of temperatures of the total temperature range 320. Additionally, or alternatively, each temperature range 330 may have a same size, where the total temperature range 320 may be split evenly into the 8 temperature ranges 330-a through 330-h to each span a same quantity of temperatures. Additionally, or alternatively, the temperature sensor 205 may split the total temperature range 320 into any quantity of temperature ranges. For example, the temperature sensor 205 may split the total temperature range 320 into 4 temperature ranges 330, as described in the example of Table 1, among other quantities of temperature ranges 330.

The total temperature range 320 may be associated with the second-order error, as described with reference to FIG. 2, where each temperature range 330) may be associated with a respective portion of a second-order error. For example, the error response 325-a may represent the second-order error over the total temperature range 320 present in one or more first bits, such as one or more bits 235-a output from the digital logic circuit 230 of FIG. 2. In some examples. the error response 325-a may demonstrate a difference between a measured first temperature represented by the bits 235-a and an actual temperature of a semiconductor device. In some examples, the error response 325-a may show no error (e.g., may match an actual temperature) at temperatures 315-c and 315-d. For example, the one or more bits 235-a may indicate an actual temperature of the semiconductor device at the temperatures 315-c and 315-d, where the temperatures 315-c and 315-d may represent −10° C. and 95° C., respectively, and where the total temperature range 320 may range from −40° C. (e.g., the temperature 315-a) to 120° C. (e.g., the temperature 315-b). In some examples, the error response 325-a may be below 0) before −10° C., above 0) between −10° C. and 95° C., and below: 0) after 95° C. as shown in the error response 325-a. In some cases, the temperature sensor 205 may trim the error response 325-a so that the temperature readings are compliant with one or more standards (e.g., a JEDEC standard). For example, the temperature sensor 205 may use trim parameters, such as a gain value and an offset value, to define the error response 325-a so that the error response 325-a is at 0) at −10° C. and 95° C. The temperature sensor 205 may apply the gain and offset values using one or more counters, where the counters may use signals associated with frequencies as input. For example, a first counter may receive the signal 225-b (e.g., associated with f_{0TC}) of FIG. 2 as a clock input and may generate a clock gating signal for the second counter which may receive the signal 225-a (e.g., associated with f_{PTAT}) as clock input. In some examples, the temperature sensor 205 may trim (e.g., ignore or remove) measurements before the temperature 315-c and after the temperature 315-d based on the trim parameters.

In some examples, the temperature sensor 205 may determine one or more first-order operations corresponding to each temperature range 330 to at least partially correct the second-order error. For example, the temperature sensor 205 may determine a respective first-order operation for each of the temperature ranges 330-a through 330-h (e.g., 8 operations) based on a respective portion of the second-order error of the error response 325-a within each temperature range 330. In some examples, the temperature sensor 205 may include respective segments corresponding to each first-order operation of each temperature range 330, as described with reference to FIG. 2. In some examples, the temperature sensor 205 may apply the respective first-order equations to multiple sets of bits 235-a corresponding to multiple temperatures by routing the multiple bits 235-a through segments of a linearization circuit and outputting resulting bits 235-b as described with reference to FIG. 2. In some examples, the first-order operations for the temperature ranges 330-a through 330-h may be defined by respective first-order equations, such as described with reference to Table 1 and the related four temperature range example.

Applying the respective first-order operations for each temperature range 330 may at least partially correct the second-order error associated with the error response 325-a. For example, the second-order error of the error response 325-a (e.g., for the one or more bits 235-a) may be parabolic over the total temperature range 320, but may be relatively linear within each of the multiple temperature ranges 330) compared to the total temperature range 320, as shown in the graph 305. Each first-order operation may be configured to correct the relatively linear error of the error response 325-a within each temperature range 330. By applying the respective first-order operations within each temperature range 330, the second-order error of the error response 325-a may be accurately corrected, as opposed to applying a single first-order operation across the total temperature range 320, which may result in a relatively poor correction due to the parabolic nature of the error response 325-a. For example, the error response 325-b may correspond to an error of the resulting sets of bits 235-b, and may represent the error response 325-a at least partially corrected based on applying the respective first-order operations to multiple sets of bits 235-a. As shown in FIG. 3, a difference in temperatures indicated by bits 235-b (e.g., corresponding to the error response 325-b) and actual temperatures of the semiconductor device may be less than a difference between temperatures indicated by the bits 235-a (e.g., corresponding to the error response 325-a) and the actual temperatures of the semiconductor device. For example, an error of the error response 325-b may be linear within each of the temperature ranges 330, and may be closer to zero than the error response 325-a, resulting in an overall smaller error over the total temperature range 320.

In an illustrative example, the total temperature range 320 may be split into 4 regions with corresponding first-order operations defined by first-order equations. For example, the total temperature range 320 may be split into a first temperature range spanning from the temperature 315-a to the temperature 315-c, a second temperature range spanning from the temperature 315-c to the temperature 315-e, a third temperature range spanning from the temperature 315-e to the temperature 315-d, and a fourth temperature range spanning the temperature 315-d to the temperature 315-b. In some examples, the temperature 315-a may represent −40° C., the temperature 315-c may represent −10° C., a temperature 315-e may represent 42.5° C., the temperature 315-d may represent 95° C., and the temperature 315-b may represent 120° C., where each of the first temperature range through the fourth temperature range may be defined as shown below in Table 1.

TABLE 1

| Temperature Range | N_{raw} range | First-order equation |
|---|---|---|
| −40° C. to −10° C. | N_{raw} ≤ 120 | ${N}_{l i n} = \frac{120 - {N}_{r a w}}{136} * 16 + {N}_{r a w}$ |
| −10° C. to 42.5° C. | 120 < N_{raw} ≤ 340 | ${N}_{l i n} = \frac{120 - {N}_{r a w}}{220} * 10 + {N}_{r a w}$ |
| 42.5° C. to 95° C. | 340 < N_{raw} ≤ 540 | ${N}_{l i n} = \frac{{N}_{r a w} - 540}{200} * 10 + {N}_{r a w}$ |
| 95° C. to 120° C. | 540 < N_{raw} | ${N}_{l i n} = \frac{{N}_{r a w} - 540}{88} * 12 + {N}_{r a w}$ |

In some examples, Nₗᵢₙ may represent a value of the error response 325-b, where N_{raw} may be a raw code value resulting in the error response 325-a. For example, N_{raw} may be a raw code value represented by the one or more bits 235-a of FIG. 2, where the raw code value may correspond to a measured temperature. In some examples, N_{raw} may be within an extended code range. For example, one or more bits 235-a, 235-b, or both may be extended to a quantity of bits greater than a defined quantity, as described with reference to FIG. 2. In some cases, N_{raw} may be extended to include 10 bits or any value greater than 7 bits, where 7 bits may be an example of the defined quantity of bits. In an example, the one or more bits 235-a, 235-b, or both, may represent N_{raw}, where N_{raw} may range from 0 to 640 for a value of 10 bits (opposed to ranging from 0 to 80 with 7 bits). In some cases, N_{raw} may be based on a gain value and an offset value, the frequencies and currents described with reference to FIG. 2, or any combination thereof.

Each of the first-order equations for the first temperature range through the fourth temperature range of Table 1 may be based on one or more parameters corresponding to each of the temperature ranges. For example, each first-order equation may be based on the general formula of

$${N}_{l i n} = \frac{A - {N}_{raw}}{B} * C + {N}_{raw} ,$$

where the values of A, B, and C may be based on the error response 325-a within each of the temperature ranges 330. Additionally, each first-order equation may lack second-order or higher order operations compared to the second-order operations (e.g., accumulate and add) described with reference to FIG. 2. In an example, the values of 120, 136, and 16 may be based on determining a corresponding portion of the error response 325-a between −40° C. and −10° C. and may be selected or weighted to optimize a linearization of the portion. The other first-order equations may similarly include numerical values that are selected or weighted to correct or linearize corresponding portions of the error response 325-a within each respective temperature range 330. By applying the first-order equations, the temperature sensor 205 may implement a first-order operation for the first temperature range through the fourth temperature range, as described herein.

In some examples, first-order equations may be programmed at the semiconductor device. For example, the values in Table 1 (e.g., A, B, and C) for each first-order equation may be set during manufacture of the semiconductor device. In some examples, trim values, such as gain values and offset values, may also be set during manufacture. In some cases, multiple segments of a linearization circuit, such as the linearization circuit 240, may be determined and manufactured based on the values of Table 1 (e.g., A, B, and C) for each first-order equation, based on the trim values, or both. In some examples, splitting the total temperature range 320 into more temperature ranges 330 (e.g., more than 4) may result in a larger chip area as well as a greater accuracy in resulting temperature measurements and a greater corrected error, while using fewer temperature ranges 330 may result in a smaller chip area, but with generally less accuracy of the error correction. In some examples, implementing first-order operations for corresponding temperature ranges 330 may result in an accurate temperature output while reducing an occupied chip area and a complexity of calculations and circuitry compared to applying second-order operations as described with reference to FIG. 2.

FIG. 4 illustrates an example of a temperature diagram 400 that supports temperature sensor linearization techniques in accordance with examples as disclosed herein. In some examples, the temperature diagram 400 may implement aspects of a system 100 as described with reference to FIG. 1, a circuit 200 as described with reference to FIG. 2, a temperature diagram 300 as described with reference to FIG. 3, or any combination thereof. For example, the temperature diagram 400 may include a graph 405-a, which may represent codes of one or more input and output temperatures of a temperature sensor (e.g., a temperature sensor 205). Additionally, the temperature diagram 400 may include a graph 405-b, which may represent an error of one or more measured temperatures, as described with reference to FIG. 3. In some examples, the graphs 405-a and 405-b may represent codes and corresponding errors of different temperatures for a single temperature range 330 of FIG. 3. For example, the graphs 405 may each span a temperature range 410, which may correspond to one of the temperature ranges 330-a through 330-h or another temperature range 330) (e.g., before temperature 315-c, between the temperature 315-c and temperature 315-e, between the temperature 315-e and temperature 315-d, or after the temperature 315-d), which may range from a temperature 415-a to a temperature 415-b.

In some examples, the graph 405-a may represent different codes plotted against temperatures of the temperature range 410. For example, each temperature of the temperature range 410 may be represented by a corresponding code ranging from 0 to 640 as described with reference to FIG. 3. The graph 405-a may range from a code 420-a to a code 420-b on a code axis plotted against the temperature axis. In some examples, the graph 405-a may include the code plot 425-a and the code plot 425-b, which may represent one or more codes represented by the one or more bits 235-a and the one or more bits 235-b, respectively. For example, the code plot 425-a may represent the one or more bits 235-a before linearization, and the code plot 425-b may represent the one or more bits 235-b after routing the one or more bits 235-a through the linearization circuit 240 described with reference to FIG. 2. Similarly, the graph 405-b may represent an error corresponding to the one or more bits 235-a and 235-b ranging from an error 430 to 0. The graph 405-b may include an error plot 435-a representing the error corresponding to the one or more bits 235-a and may include an error plot 435-b representing the error corresponding to the one or more bits 235-b.

The code plot 425-a and the error plot 435-a may represent an error of the one or more bits 235-a. For example, the code plot 425-a may be less than 0, such as −16, at an actual temperature of −40° C. (e.g., temperature 415-a). However, −40° C. may be represented by the code 0, so the code plot 425-a may be erroneous at −40° C., as shown in the graph 405-a. In some examples, the code plot 425-a may be accurate and may lack an error at the temperature 415-b. For example, the code plot 425-a may be at a code of 120 at −10° C. (e.g., the temperature 415-b). The error plot 435-a may reach 0 at −10° C., as −10° C. may be as represented by the code of 120. In some examples, the graphs 405-a and 405-b may represent a temperature range 330 ending at the temperature 315-c in FIG. 3, where the error is 0 at the temperature 315-c due to one or more parameters or trim operations as described with reference to FIG. 2.

Applying a first-order operations corresponding to the temperature range 410 may correct an error of the one or more bits 235-a corresponding to the code plot 425-a and the error plot 435-a. For example, the code plot 425-b may represent a corrected code plot 425 corresponding to codes represented by the one or more bits 235-b output from the linearization circuit 240 of FIG. 2. As shown in the graph 405-a, the code plot 425-b may be 0 at the temperature 415-a and may be at the code 420-b at the temperature 415-b, which may represent correct codes as described herein. For example, the code plot 425-b may range from a code 0) at −40° C. to a code of 120 at −10° C., where the error plot 435-b may be 0 from −40° C. (the temperature 415-a) to −10° C. (the temperature 415-b) as shown in the graph 405-b. In some examples, the error plot 435-b may be non-zero from −40° C. to −10° C. and may be partially corrected as shown by the error response 325-b in FIG. 3. In some examples, implementing first-order operations for the temperature range 410 may result in an accurate temperature output, while reducing a complexity of calculations and circuitry compared to applying second-order operations or multiply and accumulate operations as described herein.

FIG. 5 illustrates a block diagram 500 of a temperature sensor 520 associated with a semiconductor device that supports temperature sensor linearization techniques in accordance with examples as disclosed herein. The temperature sensor 520 may be an example of aspects of a temperature sensor as described with reference to FIGS. 1 through 4. The temperature sensor 520, or various components thereof, may be an example of means for performing various aspects of temperature sensor linearization techniques as described herein. For example, the temperature sensor 520 may include a temperature bit reception component 525, a temperature range component 530, a first-order operation component 535, a corrected temperature bit output component 540, a temperature bit generation component 545, a temperature bit output component 550, or any combination thereof. Each of these components may communicate, directly or indirectly, with one another (e.g., via one or more buses).

The temperature bit reception component 525 may be configured as or otherwise support a means for receiving, at a circuit of a temperature sensor associated with a semiconductor device (e.g., temperature sensor 520), one or more first bits indicating a first temperature associated with the semiconductor device. The temperature range component 530 may be configured as or otherwise support a means for determining that the first temperature indicated by the one or more first bits is within a first temperature range of a plurality of temperature ranges, the plurality of temperature ranges each spanning a respective portion of a total temperature range measurable by the temperature sensor. The first-order operation component 535 may be configured as or otherwise support a means for applying, based at least in part on the first temperature being within the first temperature range, a first-order operation corresponding to the first temperature range to the one or more first bits to determine one or more second bits indicating a second temperature associated with the semiconductor device. The corrected temperature bit output component 540 may be configured as or otherwise support a means for outputting. from the circuit of the temperature sensor, the one or more second bits indicating the second temperature.

In some examples, the temperature bit reception component 525 may be configured as or otherwise support a means for receiving, at the circuit of the temperature sensor after outputting the one or more second bits, one or more third bits indicating a third temperature associated with the semiconductor device. In some examples, the temperature range component 530 may be configured as or otherwise support a means for determining that the third temperature indicated by the one or more third bits is within a second temperature range of the plurality of temperature ranges, where the second temperature range is different from the first temperature range. In some examples, the first-order operation component 535 may be configured as or otherwise support a means for applying. based at least in part on the third temperature being within the second temperature range, a second first-order operation corresponding to the second temperature range to the one or more third bits to determine one or more fourth bits indicating a fourth temperature associated with the semiconductor device. In some examples, the corrected temperature bit output component 540 may be configured as or otherwise support a means for outputting, from the circuit of the temperature sensor, the one or more fourth bits indicating the fourth temperature.

In some examples, the second first-order operation corresponding to the second temperature range is different from the first-order operation corresponding to the first temperature range.

In some examples, the temperature bit generation component 545 may be configured as or otherwise support a means for generating, at a second circuit of the temperature sensor, the one or more first bits based at least in part on a first current and a second current, where the first current is based at least in part on measuring an actual temperature of the semiconductor device and the second current corresponds to a reference current. In some examples, the temperature bit output component 550 may be configured as or otherwise support a means for outputting the one or more first bits from the second circuit of the temperature sensor to the circuit of the temperature sensor based at least in part on the generating.

In some examples, the first-order operation component 535 may be configured as or otherwise support a means for determining the first-order operation based at least in part on a second-order error associated with the first temperature range, where applying the first-order operation to the one or more first bits is based at least in part on the determining. In some examples, the second-order error is based at least in part on one or more characteristics of a substrate associated with the semiconductor device.

In some examples, the first-order operation component 535 may be configured as or otherwise support a means for determining a respective first-order operation for each temperature range of the plurality of temperature ranges based at least in part on a respective second-order error corresponding to each temperature range, where applying the first-order operation to the one or more first bits is based at least in part on the determining. In some examples, a difference between the first temperature and an actual temperature of the semiconductor device is greater than a difference between the second temperature and the actual temperature based at least in part on applying the first-order operation to the one or more first bits.

In some examples, each respective portion of the total temperature range spans a respective quantity of temperatures. In some examples, one or more of the respective quantities of temperatures are different. In some examples, each respective quantity of temperatures includes a same quantity. In some examples, a first quantity of the one or more first bits is greater than 7 bits, or a second quantity of the one or more second bits is greater than 7 bits, or a combination thereof. In some examples, the semiconductor device includes a temperature sensor including one or more memory cells. In some examples, the semiconductor device includes a CMOS device.

FIG. 6 illustrates a flowchart showing a method 600 that supports temperature sensor linearization techniques in accordance with examples as disclosed herein. The operations of method 600 may be implemented by a temperature sensor associated with a semiconductor device or its components as described herein. For example, the operations of method 600 may be performed by a temperature sensor as described with reference to FIGS. 1 through 5. In some examples, a temperature sensor may execute a set of instructions to control the functional elements of the device to perform the described functions. Additionally, or alternatively, the temperature sensor may perform aspects of the described functions using special-purpose hardware.

At 605, the method may include receiving, at a circuit of a temperature sensor associated with a semiconductor device, one or more first bits indicating a first temperature associated with the semiconductor device. The operations of 605 may be performed in accordance with examples as disclosed herein. In some examples, aspects of the operations of 605 may be performed by a temperature bit reception component 525 as described with reference to FIG. 5.

At 610, the method may include determining that the first temperature indicated by the one or more first bits is within a first temperature range of a plurality of temperature ranges, the plurality of temperature ranges each spanning a respective portion of a total temperature range measurable by the temperature sensor. The operations of 610 may be performed in accordance with examples as disclosed herein. In some examples, aspects of the operations of 610 may be performed by a temperature range component 530 as described with reference to FIG. 5.

At 615, the method may include applying, based at least in part on the first temperature being within the first temperature range, a first-order operation corresponding to the first temperature range to the one or more first bits to determine one or more second bits indicating a second temperature associated with the semiconductor device. The operations of 615 may be performed in accordance with examples as disclosed herein. In some examples, aspects of the operations of 615 may be performed by a first-order operation component 535 as described with reference to FIG. 5.

At 620, the method may include outputting, from the circuit of the temperature sensor, the one or more second bits indicating the second temperature. The operations of 620 may be performed in accordance with examples as disclosed herein. In some examples, aspects of the operations of 620 may be performed by a corrected temperature bit output component 540 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving, at a circuit of a temperature sensor associated with a semiconductor device, one or more first bits indicating a first temperature associated with the semiconductor device: determining that the first temperature indicated by the one or more first bits is within a first temperature range of a plurality of temperature ranges, the plurality of temperature ranges each spanning a respective portion of a total temperature range measurable by the temperature sensor: applying, based at least in part on the first temperature being within the first temperature range, a first-order operation corresponding to the first temperature range to the one or more first bits to determine one or more second bits indicating a second temperature associated with the semiconductor device: and outputting, from the circuit of the temperature sensor, the one or more second bits indicating the second temperature.

Aspect 2: The method, apparatus, or non-transitory computer-readable medium of aspect 1, further including operations, features, circuitry, logic, means, or instructions, or any combination thereof for receiving, at the circuit of the temperature sensor after outputting the one or more second bits, one or more third bits indicating a third temperature associated with the semiconductor device: determining that the third temperature indicated by the one or more third bits is within a second temperature range of the plurality of temperature ranges, where the second temperature range is different from the first temperature range: applying. based at least in part on the third temperature being within the second temperature range, a second first-order operation corresponding to the second temperature range to the one or more third bits to determine one or more fourth bits indicating a fourth temperature associated with the semiconductor device: and outputting, from the circuit of the temperature sensor, the one or more fourth bits indicating the fourth temperature.

Aspect 3: The method, apparatus, or non-transitory computer-readable medium of aspect 2, where the second first-order operation corresponding to the second temperature range is different from the first-order operation corresponding to the first temperature range.

Aspect 4: The method, apparatus, or non-transitory computer-readable medium of any of aspects 1 through 3, further including operations, features, circuitry, logic, means, or instructions, or any combination thereof for generating, at a second circuit of the temperature sensor, the one or more first bits based at least in part on a first current and a second current, where the first current is based at least in part on measuring an actual temperature of the semiconductor device and the second current corresponds to a reference current and outputting the one or more first bits from the second circuit of the temperature sensor to the circuit of the temperature sensor based at least in part on the generating.

Aspect 5: The method, apparatus, or non-transitory computer-readable medium of any of aspects 1 through 4, further including operations, features, circuitry, logic, means, or instructions, or any combination thereof for determining the first-order operation based at least in part on a second-order error associated with the first temperature range, where applying the first-order operation to the one or more first bits is based at least in part on the determining.

Aspect 6: The method, apparatus, or non-transitory computer-readable medium of aspect 5, where the second-order error is based at least in part on one or more characteristics of a substrate associated with the semiconductor device.

Aspect 7: The method, apparatus, or non-transitory computer-readable medium of any of aspects 1 through 6, further including operations, features, circuitry, logic, means, or instructions, or any combination thereof for determining a respective first-order operation for each temperature range of the plurality of temperature ranges based at least in part on a respective second-order error corresponding to each temperature range, where applying the first-order operation to the one or more first bits is based at least in part on the determining.

Aspect 8: The method, apparatus, or non-transitory computer-readable medium of any of aspects 1 through 7, where a difference between the first temperature and an actual temperature of the semiconductor device is greater than a difference between the second temperature and the actual temperature based at least in part on applying the first-order operation to the one or more first bits.

Aspect 9: The method, apparatus, or non-transitory computer-readable medium of any of aspects 1 through 8, where each respective portion of the total temperature range spans a respective quantity of temperatures.

Aspect 10: The method, apparatus, or non-transitory computer-readable medium of aspect 9, where one or more of the respective quantities of temperatures are different.

Aspect 11: The method, apparatus, or non-transitory computer-readable medium of aspect 9, where each respective quantity of temperatures includes a same quantity.

Aspect 12: The method, apparatus, or non-transitory computer-readable medium of any of aspects 1 through 11, where a first quantity of the one or more first bits is greater than 7 bits, or a second quantity of the one or more second bits is greater than 7 bits, or a combination thereof.

Aspect 13: The method, apparatus, or non-transitory computer-readable medium of any of aspects 1 through 12, where the semiconductor device includes a memory device including one or more memory cells.

Aspect 14: The method, apparatus, or non-transitory computer-readable medium of any of aspects 1 through 13, where the semiconductor device includes a CMOS device.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 15: An apparatus, including: a first circuit of a temperature sensor associated with a semiconductor device, the first circuit configured to generate and output one or more first bits indicating a first temperature associated with the semiconductor device: and a second circuit of the temperature sensor, the second circuit configured to: determine that the first temperature indicated by the one or more first bits is within a first temperature range of a plurality of temperature ranges, the plurality of temperature ranges each spanning a respective portion of a total temperature range measurable by the temperature sensor: and output, based at least in part on the first temperature being within the first temperature range, one or more second bits indicating a second temperature associated with the semiconductor device, the one or more second bits based at least in part on the one or more first bits and a first-order operation corresponding to the first temperature range.

Aspect 16: The apparatus of aspect 15, where the first circuit is further configured to output, after outputting the one or more first bits, one or more third bits indicating a third temperature associated with the semiconductor device, and where the second circuit is further configured to: determine that the third temperature indicated by the one or more third bits is within a second temperature range of the plurality of temperature ranges, where the second temperature range is different from the first temperature range: and output, based at least in part on the third temperature being within the second temperature range, one or more fourth bits indicating a fourth temperature associated with the semiconductor device, the one or more fourth bits based at least in part on the one or more third bits and a second first-order operation corresponding to the second temperature range.

Aspect 17: The apparatus of any of aspects 15 through 16, where the apparatus further includes: a third circuit of the temperature sensor configured to output a first current and a second current, where the first current is based at least in part on an actual temperature of the semiconductor device the second current corresponds to a reference current; and a fourth circuit of the temperature sensor configured to output a first signal associated with a first frequency that is based at least in part on the first current and a second signal associated with a second frequency that is based at least in part on the second current, where generating the one or more first bits is based at least in part on comparing the first signal to the second signal.

Aspect 18: The apparatus of aspect 17, where the third circuit includes a bandgap circuit, and where the fourth circuit includes a first oscillator configured to output the first signal associated with the first frequency based at least in part on the first current and a second oscillator configured to output the second signal associated with the second frequency based at least in part on the second current.

Aspect 19: The apparatus of any of aspects 15 through 18, where each segment of a plurality of segments of the second circuit is associated with a respective temperature range and a respective first-order operation, where the second circuit is configured to: apply the first-order operation corresponding to the first temperature range to the one or more first bits by routing the one or more first bits through a first segment of the plurality of segments of the second circuit associated with the first temperature range, where the one or more second bits are output based at least in part on routing the one or more first bits through the first segment.

Aspect 20: The apparatus of aspect 19, where the first-order operation is based at least in part on a second-order error associated with the first temperature range.

Aspect 21: The apparatus of aspect 20, where the second-order error is based at least in part on one or more characteristics associated with a substrate of the semiconductor device.

Aspect 22: The apparatus of any of aspects 19 through 21, where each respective first-order operation is based at least in part on a respective second-order error corresponding to each temperature range of the plurality of temperature ranges.

Aspect 23: The apparatus of any of aspects 15 through 22, where a difference between the first temperature and an actual temperature of the semiconductor device is greater than a difference between the second temperature and the actual temperature based at least in part on applying the first-order operation to the one or more first bits.

Aspect 24: The apparatus of any of aspects 15 through 23, where each respective portion of the total temperature range spans a respective quantity of temperatures.

Aspect 25: The apparatus of aspect 24, where one or more of the respective quantities of temperatures are different.

Aspect 26: The apparatus of aspect 24, where each respective quantity of temperatures includes a same quantity.

Aspect 27: The apparatus of any of aspects 15 through 26, where a first quantity of the one or more first bits is greater than 7 bits, or a second quantity of the one or more second bits is greater than 7 bits, or a combination thereof.

Aspect 28: The apparatus of any of aspects 15 through 27, where the semiconductor device includes a memory device including one or more memory cells.

Aspect 29: The apparatus of any of aspects 15 through 28, where the semiconductor device includes a CMOS device.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal: however, the signal may represent a bus of signals, where the bus may have a variety of bit widths.

The terms “electronic communication,” “conductive contact.” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. At any given time, a conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component initiates a change that allows signals to flow between the other components over a conductive path that previously did not permit signals to flow:

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component (e.g., a transistor) discussed herein may represent a field-effect transistor (FET), and may comprise a three-terminal component including a source (e.g., a source terminal), a drain (e.g., a drain terminal), and a gate (e.g., a gate terminal). The terminals may be connected to other electronic components through conductive materials (e.g., metals, alloys). The source and drain may be conductive, and may comprise a doped (e.g., heavily-doped, degenerate) semiconductor region. The source and drain may be separated by a doped (e.g., lightly-doped) semiconductor region or channel. If the channel is n-type (e.g., majority carriers are electrons), then the FET may be referred to as a n-type FET. If the channel is p-type (e.g., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration.” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
receiving, at a circuit of a temperature sensor associated with a semiconductor device, one or more first bits indicating a first temperature associated with the semiconductor device:
determining that the first temperature indicated by the one or more first bits is within a first temperature range of a plurality of temperature ranges, the plurality of temperature ranges each spanning a respective portion of a total temperature range measurable by the temperature sensor:
applying, based at least in part on the first temperature being within the first temperature range, a first-order operation corresponding to the first temperature range to the one or more first bits to determine one or more second bits indicating a second temperature associated with the semiconductor device; and
outputting, from the circuit of the temperature sensor, the one or more second bits indicating the second temperature.

2. The method of claim 1, further comprising:
receiving, at the circuit of the temperature sensor after outputting the one or more second bits, one or more third bits indicating a third temperature associated with the semiconductor device:
determining that the third temperature indicated by the one or more third bits is within a second temperature range of the plurality of temperature ranges, wherein the second temperature range is different from the first temperature range:
applying, based at least in part on the third temperature being within the second temperature range, a second first-order operation corresponding to the second temperature range to the one or more third bits to determine one or more fourth bits indicating a fourth temperature associated with the semiconductor device; and
outputting, from the circuit of the temperature sensor, the one or more fourth bits indicating the fourth temperature.

3. The method of claim 2, wherein the second first-order operation corresponding to the second temperature range is different from the first-order operation corresponding to the first temperature range.

4. The method of claim 1, further comprising:
generating, at a second circuit of the temperature sensor, the one or more first bits based at least in part on a first current and a second current, wherein the first current is based at least in part on measuring an actual temperature of the semiconductor device and the second current corresponds to a reference current; and
outputting the one or more first bits from the second circuit of the temperature sensor to the circuit of the temperature sensor based at least in part on the generating.

5. The method of claim 1, further comprising:
determining the first-order operation based at least in part on a second-order error associated with the first temperature range, wherein applying the first-order operation to the one or more first bits is based at least in part on the determining.

6. The method of claim 5, wherein the second-order error is based at least in part on one or more characteristics of a substrate associated with the semiconductor device.

7. The method of claim 1, further comprising:
determining a respective first-order operation for each temperature range of the plurality of temperature ranges based at least in part on a respective second-order error corresponding to each temperature range, wherein applying the first-order operation to the one or more first bits is based at least in part on the determining.

8. The method of claim 1, wherein a difference between the first temperature and an actual temperature of the semiconductor device is greater than a difference between the second temperature and the actual temperature based at least in part on applying the first-order operation to the one or more first bits.

9. The method of claim 1, wherein each respective portion of the total temperature range spans a respective quantity of temperatures.

10. The method of claim 9, wherein one or more of the respective quantities of temperatures are different.

11. The method of claim 9, wherein each respective quantity of temperatures comprises a same quantity.

12. The method of claim 1, wherein a first quantity of the one or more first bits is greater than 7 bits, or a second quantity of the one or more second bits is greater than 7 bits, or a combination thereof.

13. The method of claim 1, wherein the semiconductor device comprises a memory device comprising one or more memory cells.

14. The method of claim 1, wherein the semiconductor device comprises a complementary metal-oxide semiconductor (CMOS) device.

15. An apparatus, comprising:
a first circuit of a temperature sensor associated with a semiconductor device, the first circuit configured to generate and output one or more first bits indicating a first temperature associated with the semiconductor device; and
a second circuit of the temperature sensor, the second circuit configured to:
determine that the first temperature indicated by the one or more first bits is within a first temperature range of a plurality of temperature ranges, the plurality of temperature ranges each spanning a respective portion of a total temperature range measurable by the temperature sensor; and
output, based at least in part on the first temperature being within the first temperature range, one or more second bits indicating a second temperature associated with the semiconductor device, the one or more second bits based at least in part on the one or more first bits and a first-order operation corresponding to the first temperature range.

16. The apparatus of claim 15, wherein the first circuit is further configured to output, after outputting the one or more first bits, one or more third bits indicating a third temperature associated with the semiconductor device, and wherein the second circuit is further configured to:
determine that the third temperature indicated by the one or more third bits is within a second temperature range of the plurality of temperature ranges, wherein the second temperature range is different from the first temperature range; and
output, based at least in part on the third temperature being within the second temperature range, one or more fourth bits indicating a fourth temperature associated with the semiconductor device, the one or more fourth bits based at least in part on the one or more third bits and a second first-order operation corresponding to the second temperature range.

17. The apparatus of claim 15, wherein the apparatus further comprises:
a third circuit of the temperature sensor configured to output a first current and a second current, wherein the first current is based at least in part on an actual temperature of the semiconductor device the second current corresponds to a reference current; and
a fourth circuit of the temperature sensor configured to output a first signal associated with a first frequency that is based at least in part on the first current and a second signal associated with a second frequency that is based at least in part on the second current, wherein generating the one or more first bits is based at least in part on comparing the first signal to the second signal.

18. The apparatus of claim 17, wherein the third circuit comprises a bandgap circuit, and wherein the fourth circuit comprises a first oscillator configured to output the first signal associated with the first frequency based at least in part on the first current and a second oscillator configured to output the second signal associated with the second frequency based at least in part on the second current.

19. The apparatus of claim 15, wherein each segment of a plurality of segments of the second circuit is associated with a respective temperature range and a respective first-order operation, wherein the second circuit is configured to:
apply the first-order operation corresponding to the first temperature range to the one or more first bits by routing the one or more first bits through a first segment of the plurality of segments of the second circuit associated with the first temperature range, wherein the one or more second bits are output based at least in part on routing the one or more first bits through the first segment.

20. An apparatus, comprising:
a controller associated with a semiconductor device, wherein the controller is configured to cause the apparatus to:
receive, at a circuit of a temperature sensor associated with the semiconductor device, one or more first bits indicating a first temperature associated with the semiconductor device;
determine that the first temperature indicated by the one or more first bits is within a first temperature range of a plurality of temperature ranges, the plurality of temperature ranges each spanning a respective portion of a total temperature range measurable by the temperature sensor;
apply, based at least in part on the first temperature being within the first temperature range, a first-order operation corresponding to the first temperature range to the one or more first bits to determine one or more second bits indicating a second temperature associated with the semiconductor device; and
outputting, from the circuit of the temperature sensor, the one or more second bits indicate the second temperature.
